(19) United States
(12) Patent Application Publication
(10) Pub. No.: US 2015/0260593 A1
(43) Pub. Date: Sep. 17, 2015

(54) MIRCO-ELECTRO-MECHANICAL SYSTEM PRESSURE SENSOR AND MANUFACTURING METHOD THEREOF

(71) Applicants: Yu-Wen Hsu, North Dist. (TW); Chia-Yu Wu, Kaohsiung (TW); Shih-Chieh Lin, Kaohsiung (TW); Shih-Ting Lin, Hualien (TW)

(72) Inventors: Yu-Wen Hsu, North Dist. (TW); Chia-Yu Wu, Kaohsiung (TW); Shih-Chieh Lin, Kaohsiung (TW); Shih-Ting Lin, Hualien (TW)

(73) Assignee: RICHTEK TECHNOLOGY CORPORATION, ZHUBEI CITY (TW)

(21) Appl. No.: 14/329,111

(22) Filed: Jul. 11, 2014

(30) Foreign Application Priority Data
Mar. 17, 2014 (TW) 103109852
Jun. 6, 2014 (TW) 103119642

(51) Int. Cl. G01L 9/00; B81B 7/00; B81C 1/00

(52) U.S. Cl. CPC G01L 9/0005; B81C 1/00293; B81B 7/0041; B81C 1/00158; B81B 2201/0264

(57) ABSTRACT

The invention provides a micro-electro-mechanical system pressure sensor. The micro-electro-mechanical system pressure sensor includes: a substrate, including at least one conductive wiring; a membrane disposed above the substrate to form a semi-open chamber between the membrane and the substrate, the semi-open chamber having an opening to receive an external pressure; and a cap, disposed above the membrane and forming an enclosed space with the membrane, the cap including a top electrode corresponding to the membrane and at least one portion of the membrane forming a bottom electrode, wherein the top and bottom electrodes form a sensing capacitor to sense the external pressure.

### CROSS REFERENCE

The present invention claims priority to TW 103109852, filed on Mar. 17, 2014, and TW 103119642, filed on Jun. 6, 2014.

### BACKGROUND OF THE INVENTION

1. Field of Invention

The present invention relates to a micro-electro-mechanical system pressure sensor, which includes a semi-open chamber to receive an external pressure and a membrane disposed over the semi-open chamber.

2. Description of Related Art

Micro-electro-mechanical system (MEMS) pressure sensors are commonly used nowadays, in applications such as altitude meters, microphones, pressure sensors in engine management systems, etc. FIG. 1 shows a prior art MEMS pressure sensor 10, which includes a membrane 11, an enclosed space 12, and a substrate 13. The membrane 11 deforms according to an external pressure P to generate a sensing signal. This prior art has an advantage of simple structure, but it has the following drawback. During manufacturing the MEMS device, the semiconductor manufacturing process uses working gases such as argon, oxygen, etc., and a minor amount of the residual working gas may still reside in the device. Such residual gas will be released (outgas) to the enclosed space 12, causing the internal pressure of the enclosed space 12 to deviate from the design value such that the sensing result is inaccurate. For reference, U.S. Pat. Nos. 6,131,466 and 6,131,466 disclose such prior art MEMS pressure sensors.

In view of the drawback in the prior art, it is desired to reduce the adverse effect of the residual gas on pressure sensing.

### SUMMARY OF THE INVENTION

According to a perspective of the present invention, a MEMS pressure sensor is provided, which comprises: a substrate including at least one conductive wiring; a membrane above the substrate to form a semi-open chamber between the membrane and the substrate, the semi-open chamber having an opening to receive an external pressure; and a cap above the membrane and forming an enclosed space with the membrane, the cap including a top electrode and a portion of the membrane forming a bottom electrode, wherein the top and bottom electrodes form a sensing capacitor to sense the external pressure; wherein the top and bottom electrodes are separately coupled to a conductive wiring.

In one embodiment of the present invention, the enclosed space is completely sealed. In another embodiment, the MEMS pressure sensor comprises a connection passage for connecting the enclosed space to a reference pressure source.

In one embodiment, the connection passage is in the cap.

In one embodiment of the present invention, the cap and the membrane are bonded through a insulating layer, and the connection passage is in the insulating layer.

In one embodiment, the membrane and the insulating layer are a silicon layer and an insulator layer of a silicon on insulator (SOI) film.

In one embodiment, the membrane includes a conductive metal layer to form a lower electrode and a mass.

In one embodiment, the MEMS pressure sensor further includes a conducting plug to couple the bottom electrode to the conductive wiring.

In one embodiment, the top electrode is coupled to the conductive wiring through a conducting plug, and the MEMS pressure sensor further comprises: an electrically isolating structure between the bottom electrode and the conducting plug, the electrically isolating structure being a gap or made of an insulating material.

In one embodiment, the MEMS pressure sensor further includes a plurality of obstacles at the opening of the semi-open chamber.

In one embodiment of the present invention, the cap includes a plurality of stoppers at a side of the cap facing the membrane.

According to another perspective, the present invention provides a manufacturing method of MEMS pressure sensor which comprises: providing a substrate including an conductive wiring; providing a membrane above the substrate to form a semi-open chamber between the membrane and the substrate, wherein at least a portion of the membrane forms a bottom electrode; coupling the membrane to the conductive wiring; providing a cap above the membrane and forming an enclosed space with the membrane, the cap including a top electrode; and coupling the top electrode to the conductive wiring; wherein the semi-open chamber includes an opening to receive an external pressure such that the membrane deforms according to the external pressure.

According to another perspective of the present invention, a manufacturing method of MEMS pressure sensor is provided. The manufacturing method comprises: providing a substrate including at least one conductive wiring; forming a first insulating layer on the substrate; forming a first conducting plug and a first portion of a second conducting plug in the first insulating layer; bonding a membrane with the substrate through the first insulating layer, to form a semi-open chamber, wherein at least a portion of the membrane forms a bottom electrode which is coupled through the first conducting plug to the conductive wiring; forming a second insulating layer on the membrane; forming a second portion of the second conducting plug in the second insulating layer; providing a cap bonded with the membrane by the second insulating layer to form an enclosed space, the cap including a top electrode which is coupled to the conductive wiring through the second conducting plug; wherein the semi-open chamber includes an opening to receive an external pressure such that the membrane deforms according to the external pressure.

The objectives, technical details, features, and effects of the present invention will be better understood with regard to the detailed description of the embodiments below, with reference to the drawings.

### BRIEF DESCRIPTION OF THE DRAWINGS

FIG. 1 shows a prior art MEMS pressure sensor.

FIG. 2A shows a cross section view of the MEMS pressure sensor according to one embodiment of the present invention, and the cross section view is taken along the cross section line AA shown in FIGS. 2D and 2E.

FIG. 2B shows a cross section view of the MEMS pressure sensor according to another embodiment of the present invention, and the cross section view is taken along the cross section line AA shown in FIGS. 2D and 2E.

FIG. 2C shows a cross section view of the MEMS pressure sensor according to yet another embodiment of the present invention, and the cross section view is taken along the cross section line AA shown in FIGS. 2D and 2E.

FIG. 2D is a local top view showing the opening 221 in FIGS. 2A-2C according to one embodiment of the present invention.

FIG. 2E is a local top view showing the opening 221 in FIGS. 2A-2C according to another embodiment of the present invention.

FIG. 3A shows a cross section view of the MEMS pressure sensor according to another embodiment of the present invention, and the cross section view is taken along the cross section line BB shown in FIG. 3B.

FIG. 3B is a local top view showing the opening 221 in FIG. 3A according to one embodiment of the present invention.

FIG. 4 shows a flowchart of a manufacturing method of a MEMS pressure sensor according to one embodiment of the present invention.

FIG. 5 shows a flowchart of a manufacturing method of a MEMS pressure sensor according to another embodiment of the present invention.

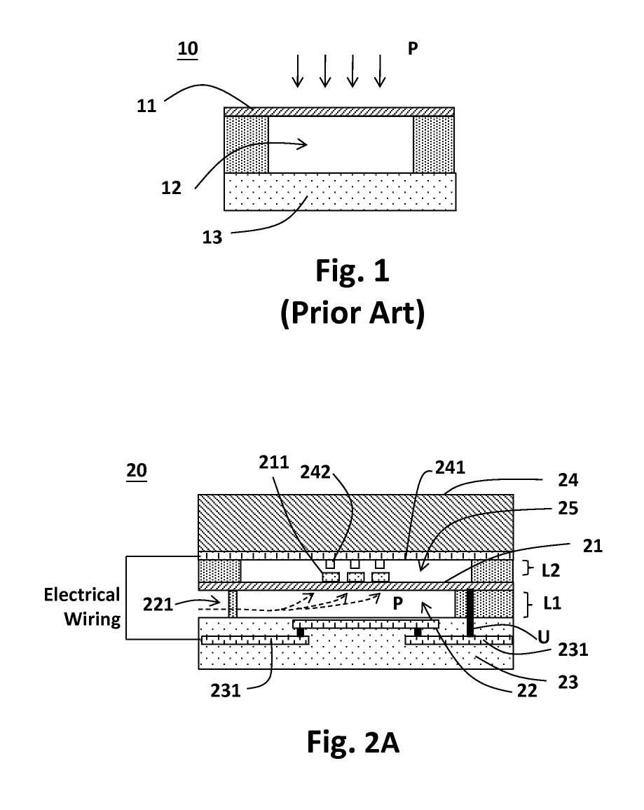

### DESCRIPTION OF THE PREFERRED EMBODIMENTS

The drawings as referred to throughout the description of the present invention are for illustration only, but not drawn according to actual scale. The orientation wordings in the description such as: above, under, left, and right are for reference with respect to the drawings, but not for limiting the actual product made according to the present invention.

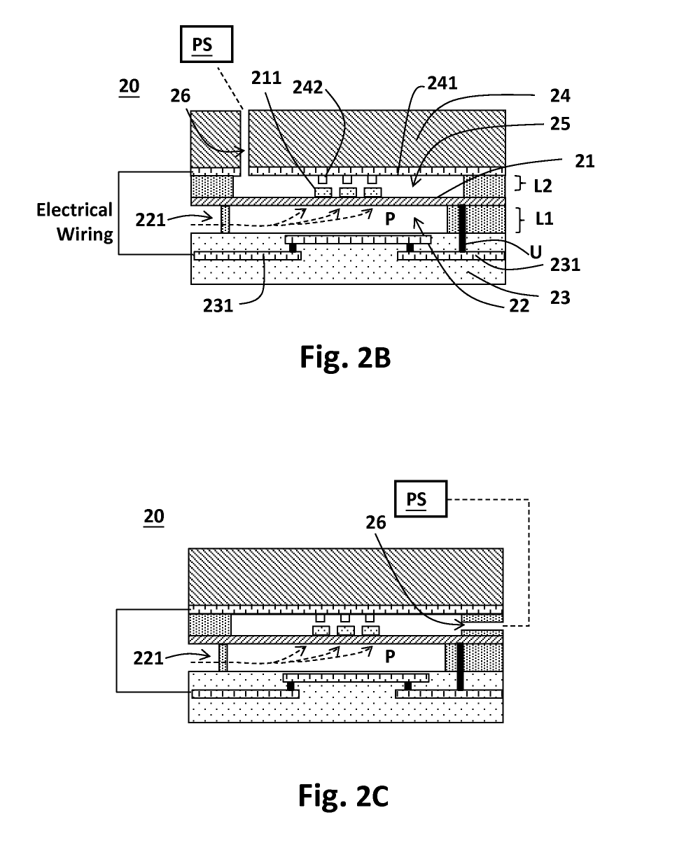

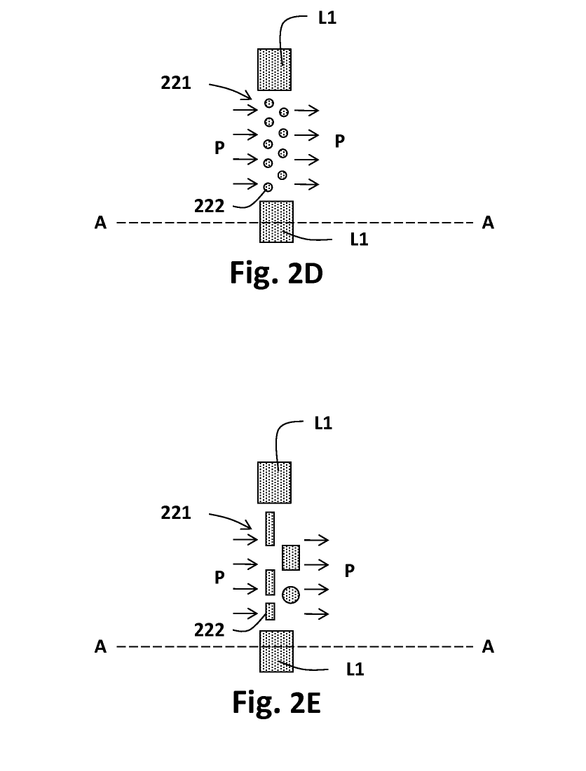

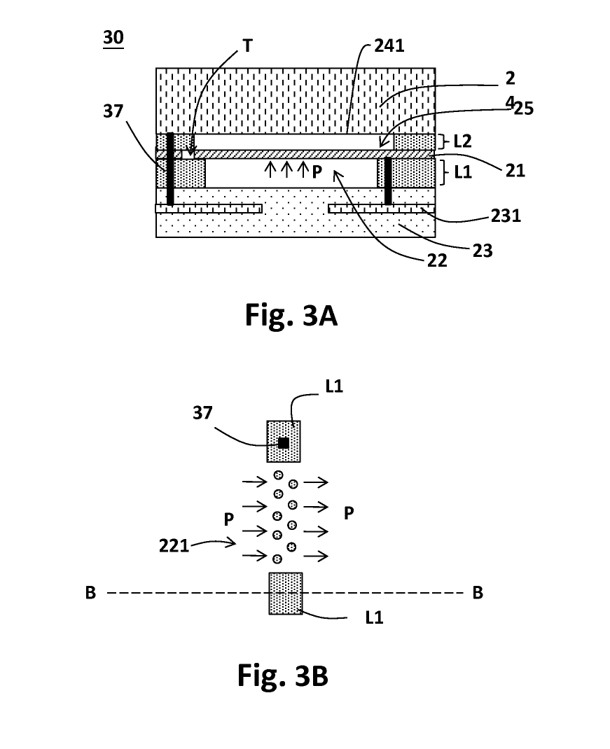

Referring to FIG. 2A, the present invention provides a MEMS pressure sensor 20 which comprises: a substrate 23 including at least one conductive wiring 231, wherein the substrate 23 includes for example but not limited to a bottom silicon substrate (or a bottom substrate made of another material) and a conductive wiring on or in the bottom silicon substrate, formed for example by steps of lithography, ion implantation, deposition, and/or etching, etc.; a semi-open chamber 22 above the conductive wiring 231, between the conductive wiring 231 and a membrane 21, the semi-open chamber 22 having an opening 221 to receive an external pressure P, wherein the membrane 21 and the substrate 23 can be bonded by a insulating layer L1 (which can be a single-layer film or a composite film having multiple layers), and preferably, the insulating layer L1 includes at least one insulating layer; for example, it can be a single insulating layer or a silicon on insulator (SOI) film; and a cap 24 above the membrane 21 and forming an enclosed space 25 with the membrane 21, the cap including a top electrode 241 and at least a portion (or all) of the membrane 21 forming a bottom electrode, wherein the top and bottom electrodes form a sensing capacitor to sense the external pressure P. The membrane 21 and the cap 24 can be bonded by a insulating layer L2 which can be a single-layer film or a composite film having multiple layers, and preferably, the insulating layer L2 includes at least one insulating layer; for example, it can be a single insulating layer or a part of an SOI film. In the embodiment using an SOI film, for example, the silicon layer of the SOI film can be used to form the membrane 21, and the insulator layer of the SOI film can be used to form the insulating layer L2. The top electrode 241 and the bottom electrode in the membrane 21 are coupled to a conductive wiring 231. In one embodiment, for example, the bottom electrode in the membrane 21 is coupled to the conductive wiring 231 through a conducting plug U, and the top electrode 241 is coupled to the conductive wiring 231 through an electrical wiring. The above is only one non-limiting example; of course, the bottom electrode in the membrane 21 can be coupled to the conductive wiring 231 through an electrical wiring, and the top electrode 241 can be coupled to the conductive wiring 231 through a conducting plug (e.g., referring to FIG. 3A).

In one embodiment, the enclosed space 25 is completely sealed such that it has a vacuum status, and the MEMS pressure sensor 20 can be used for absolute pressure sensing. In another embodiment as shown in FIGS. 2B and 2C, the MEMS pressure sensor comprises a connection passage 26 which connects the enclosed space 25 to a reference pressure source PS, and the MEMS pressure sensor 20 can be used for gauge pressure sensing. In one example, the connection passage 26 goes through the cap 24 (FIG. 2B). In another example, the connection passage 26 goes through the second insulating layer L2 (FIG. 2C). When the enclosed space 26 is connected to the reference pressure source PS through the connection passage 26, the enclosed space 25, the connection passage 26, and the reference pressure source PS as a whole form an enclosed and pressure-controllable environment.

In one embodiment, the membrane 21 includes at least one mass 211 having a thickness higher than the rest of the membrane 21. The mass 211 is preferable disposed near the center of the membrane 21 to increase the vibration scale of the membrane 21, for a higher sensing resolution. In one embodiment, the membrane 21 is totally made of a conductive material, or in another embodiment, the membrane 21 includes a conducting layer, to form the bottom electrode. Besides, the cap 24 can include at least one stopper 242 at the side of the cap 24 facing the membrane 21 (for example at a location corresponding to the mass 211), to avoid a stiction between the membrane 21 and the cap 24, or to prevent the membrane 21 from vibrating too large.

According to one embodiment of the present invention, the semi-open chamber 22 has an opening 221. FIG. 2D is a local top view showing the opening 221 in FIGS. 2B and 2C; that is, FIGS. 2B and 2C are cross section views according to the cross section line AA of FIG. 2D. As shown in FIG. 2D, in one embodiment, several obstacles 222 are disposed at the opening 221 to filter dust or other particles coming from outside. In the shown embodiment, the obstacles are cylinders arranged in two staggered rows. However, the present invention is not limited to this embodiment; the shape and arrangement of the obstacles can be otherwise, such as of different shapes, arranged in signal row, double rows, multiple rows, in different distribution densities, etc. For example, as shown in FIG. 2E, the obstacles can be of different shapes, and/or different sizes.

In the embodiment of FIG. 2B, the membrane 21 is coupled to the conductive wiring 231 through a conducting plug U, for transmitting sensing signal to the conductive wiring 231, and the top electrode 241 is coupled through an electrical wiring to the conductive wiring 231. In another embodiment shown in FIG. 3A, the top electrode 241 transmits the sensing signal to the conductive wiring through another conducting plug 37. Because the top and bottom electrodes should not be shorted to the same voltage level, the conducting plug 37 should not be shorted to the bottom electrode in the membrane 21; therefore, an electrically isolating structure T is preferably provided between the bottom electrode and the conducting plug 37, wherein the electrically isolating structure T can be a gap or made of an insulating material.

Similar to FIGS. 2D and 2E, FIG. 3B shows a local top view of the opening 221. Although the opening 221 is not shown in FIG. 3A, according to the description with regard to the aforementioned embodiment, the semi-open chamber 22 of the MEMS pressure sensor 30 has an opening 221 to receive the external pressure P. Further, FIG. 3A shows that the mass 211, the stopper 242, the connection passage 26, and the reference pressure source PS are not absolutely necessary.

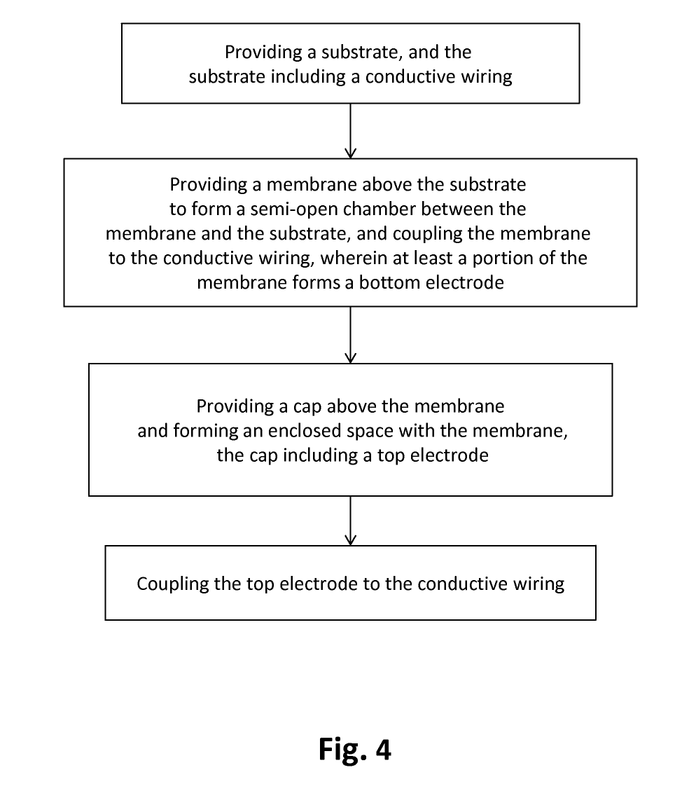

According to another perspective, referring to FIG. 4, the present invention provides a manufacturing method of MEMS pressure sensor which comprises: providing a substrate including an conductive wiring; providing a membrane above the substrate to forma semi-open chamber between the membrane and the substrate, wherein at least a portion of the membrane forms a bottom electrode and the portion of the membrane is coupled to the conductive wiring; providing a cap above the membrane to form an enclosed space with the membrane, the cap including a top electrode corresponding to the bottom electrode; and coupling the top electrode to the conductive wiring. The semi-open chamber includes an opening to receive an external pressure such that the membrane deform according to the external pressure, to sense the external pressure. The above-mentioned steps are not restricted to the sequence as described; for example, the cap can be bonded above the membrane, and thereafter the membrane and the substrate are coupled. In addition, one step can be divided into several sub-steps; taking the step of forming the semi-open chamber as an example: a sealed chamber (not shown) can be formed at first, and then an opening (opening 221 of FIGS. 2A-2E) can formed on any wall, ceiling or bottom of the chamber (now it is not sealed) to connect the chamber with the external pressure. Furthermore, the step of coupling the membrane to conductive wiring can be separated from the step of bonding the membrane and the substrate; for example, the step of coupling the membrane to conductive wiring can be done later. Thus, the arrangement of the steps can vary, depending on practical needs.

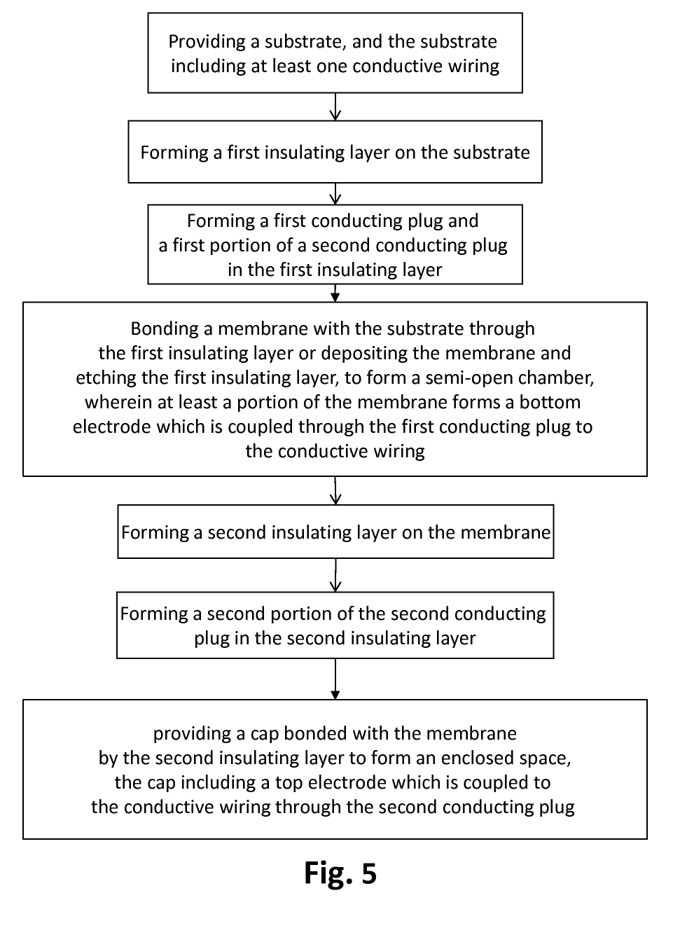

FIG. 5 shows a manufacturing method of a MEMS pressure sensor according to another embodiment of the present invention, wherein at least some of the steps are compatible with the standard complementary metal oxide semiconductor manufacturing process. The manufacturing method comprises: providing a substrate including a conductive wiring; forming a first insulating layer on the substrate; forming a first conducting plug and a first portion of a second conducting plug in the first insulating layer; bonding a membrane with the substrate through the first insulating layer, or depositing the membrane and then etching the first insulating layer (for example through the opening 221 in the first insulating layer, in this case the region to be etched and the region to be kept should be made of different materials, and a suitable etchant should be used), to form a semi-open chamber, wherein at least one portion of the membrane forms a bottom electrode which is coupled through the first conducting plug to the conductive wiring; forming a second insulating layer on the membrane; forming a second portion of the second conducting plug in the second insulating layer; and providing a cap bonded with the membrane by the second insulating layer to form an enclosed space, the cap including a top electrode which is coupled to the conductive wiring through the second conducting plug. The semi-open chamber includes an opening to receive an external pressure such that the membrane deform according to the external pressure, for sensing the external pressure.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. An embodiment or a claim of the present invention does not need to achieve all the objectives or advantages of the present invention. The title and abstract are provided for assisting searches but not for limiting the scope of the present invention.

What is claimed is:

1. A micro-electro-mechanical system (MEMS) pressure sensor, comprising:
a substrate including at least one conductive wiring;
a membrane above the substrate, forming a semi-open chamber between the membrane and the substrate, the semi-open chamber having an opening to receive an external pressure; and
a cap above the membrane and forming an enclosed space with the membrane, the cap including a top electrode and at least a portion of the membrane forming a bottom electrode, wherein the top and bottom electrodes forma sensing capacitor to sense the external pressure;
wherein the top and bottom electrodes are separately coupled to the conductive wiring.

2. The MEMS pressure sensor of claim 1, wherein the enclosed space is completely sealed, or the MEMS pressure sensor comprises a connection passage which connects the enclosed space to a reference pressure.

3. The MEMS pressure sensor of claim 2, wherein the connection passage is in the cap.

4. The MEMS pressure sensor of claim 2, wherein the cap and the membrane are bonded by a insulating layer, and the connection passage is in the insulating layer.

5. The MEMS pressure sensor of claim 4, wherein the membrane and the insulating layer are a silicon layer of a silicon-on-insulator film and an insulator layer of the silicon-on-insulator film, respectively.

6. The MEMS pressure sensor of claim 1, wherein the membrane includes at least one mass having a higher thickness than the rest of the membrane.

7. The MEMS pressure sensor of claim 1, further comprising a conducting plug to couple the bottom electrode to the conductive wiring.

8. The MEMS pressure sensor of claim 1, wherein the top electrode is coupled to the conductive wiring through a conducting plug, and the MEMS pressure sensor further comprises: an electrically isolating structure between the bottom electrode and the conducting plug, the electrically isolating structure being a gap or made of an insulating material.

9. The MEMS pressure sensor of claim 1, further comprising a plurality of obstacles at the opening of the semi-open chamber.

10. The MEMS pressure sensor of claim 1, wherein the cap includes a plurality of stoppers at a side of the cap facing the membrane.

11. The MEMS pressure sensor of claim 1, wherein the substrate includes a bottom silicon substrate.

12. A manufacturing method of MEMS pressure sensor, comprising:
providing a substrate including an conductive wiring;
providing a membrane above the substrate to form a semi-open chamber between the membrane and the substrate, wherein at least a portion of the membrane forms a bottom electrode;
coupling the membrane to the conductive wiring; and
providing a cap above the membrane and forming an enclosed space with the membrane, the cap including a top electrode; and
coupling the top electrode to the conductive wiring;
wherein the semi-open chamber includes an opening to receive an external pressure such that the membrane deforms according to the external pressure.

13. The manufacturing method of MEMS pressure sensor of claim 12, wherein the step of providing a cap above the membrane includes: bonding the cap and the membrane by an insulating layer, wherein the membrane and the insulating layer are a silicon layer of a silicon-on-insulator film and an insulator layer of the silicon-on-insulator film, respectively.

14. The manufacturing method of MEMS pressure sensor of claim 11, wherein the substrate includes a bottom silicon substrate.

15. A manufacturing method of MEMS pressure sensor, comprising:
providing a substrate including a conductive wiring;
forming a first insulating layer on the substrate;
forming a first conducting plug and a first portion of a second conducting plug in the first insulating layer;
bonding a membrane with the substrate through the first insulating layer, or depositing the membrane and etching the first insulating layer, to form a semi-open chamber, wherein at least a portion of the membrane forming a bottom electrode;
coupling the bottom electrode through the first conducting plug to the conductive wiring;
forming a second insulating layer on the membrane;
forming a second portion of the second insulating layer in the second insulating layer; and
providing a cap bonded with the membrane by the second insulating layer to form an enclosed space, the cap including a top electrode which is coupled to the conductive wiring through the second conducting plug;
wherein the semi-open chamber includes an opening to receive an external pressure such that the membrane deforms according to the external pressure.

16. The manufacturing method of MEMS pressure sensor of claim 15, wherein the substrate includes a bottom silicon substrate.
